(19) United States
(12) Patent Application Publication
(10) Pub. No.: US 2007/0091582 A1
(43) Pub. Date: Apr. 26, 2007

(54) Cover-slidable mobile phone

(75) Inventors: Hung-Chung Ku, Taipei (TW); Chih-Kai Hu, Taipei (TW); Pin-An Hsieh, Taipei (TW)

Correspondence Address: RABIN & Berdo, PC, 1101 14TH STREET, NW, SUITE 500, WASHINGTON, DC, 20005, US

(73) Assignee: ASUSTek COMPUTER INC., Taipei (TW)

(21) Appl. No.: 11/584,529

(22) Filed: Oct. 23, 2006

(30) Foreign Application Priority Data
Oct. 24, 2005 (TW) 94137177

(51) Int. Cl. H05K 5/02

(52) U.S. Cl. 361/814; 361/752; 455/575.4

(57) ABSTRACT

A mobile phone includes a main body, a first magnetic device, a slide cover and a second magnetic device. The first magnetic device is disposed on the main body. The slide cover is slidably connected to the main body and can slide relative to the main body. The second magnetic device is disposed on the slide cover. When the slide cover moves to a distance relative to the main body, the first magnetic device attracts the second magnetic device so that the slide cover slides to a first positioning point.

This application claims the benefit of Taiwan application Serial No. 94137177, filed Oct. 24, 2005, the subject matter of which is incorporated herein by reference.

### BACKGROUND OF THE INVENTION

1. Field of the Invention

The invention relates in general to a mobile phone, and more particularly to a cover-slidable mobile phone.

2. Description of the Related Art

Mobile phone has been popular in modern people's daily lives. Especially, the cover-slidable mobile phone stands for a fashionable and multi-function electronic product. In additional to the functions of dialing and receiving phone-calls, this style of mobile phone provides the function of a display panel or camera by the slidable cover.

There are two classes of cover-slidable mobile phones in present. One class is an manual type of cover-slidable mobile phone, that is, the user has to move the cover by hand in usage. The other class is a half-automatic type of cover-slidable mobile phone, that is, the user needs only to shift the cover to a predetermined distance and then the cover can automatically move to a completely close or open state.

The user might require some effort in opening the cover and feel unhandy as using an manual cover-slidable mobile phone, while he/she could feel it saving more time and electrical power in usage of a half-automatic cover-slidable mobile phone. Therefore, the half-automatic mobile phone has become a mainstream of the cover-slidable mobile phone. However, in the method for moving the cover of a common cover-slidable mobile phone, a specific mechanism needs to be used to control the process of opening or closing the cover. Such mechanism has to be able to move the cover to a certain distance before the cover can automatically position to the open or close point. Therefore, the mechanism has usually a much complicated structure, thereby increasing the cost of the cover-slidable mobile phone.

### SUMMARY OF THE INVENTION

It is therefore an object of the invention to provide a cover-slidable mobile phone with a simplified structure and design whose cost can be reduced to improve competitive advantage of the product.

The invention achieves the above-identified object by providing a embodiment of a mobile phone including a main body, a first magnetic device, a slide cover and a second magnetic device. The first magnetic device is disposed on the main body. The slide cover is slidably connected to the main body and can slide relative to the main body. The second magnetic device is disposed on the slide cover. When the slide cover moves to a distance relative to the main body, the first magnetic device attracts the second magnetic device so that the slide cover can slide to a first positioning point.

The invention achieves the above-identified object by providing a cover-slidable mobile phone including a main body, a slide cover, a first magnetic device, a second magnetic device and a third magnetic device. The slide cover is slidably connected to the main body. The first magnetic device is disposed at one end of the main body. The second magnetic device is disposed on the slide cover. When the slide cover moves to a distance relative to the main body, the first magnetic device is attracted to the second magnetic device so that the slide cover moves to a first positioning point. The third magnetic device is disposed at the other end of the main body. When the second magnetic device moves close to the third magnetic device, the third magnetic device attracts the second magnetic device so that the slide cover moves to a second positioning point.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1A is an explored diagram of a mobile phone according to a preferred embodiment of the invention.

FIG. 1B is a lateral diagram of the mobile phone with the slide cover located at the first positioning point.

FIG. 1C is a lateral diagram of the mobile phone with the slide cover located at the second positioning point.

### DETAILED DESCRIPTION OF THE INVENTION

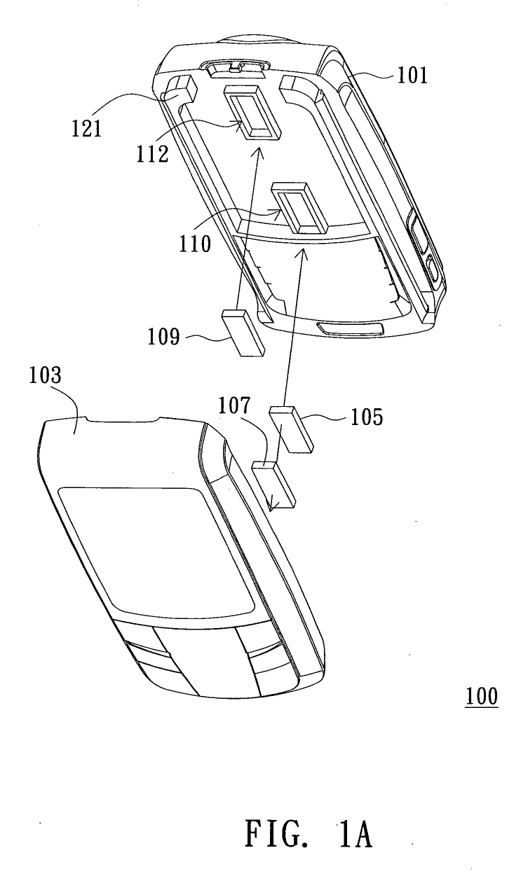

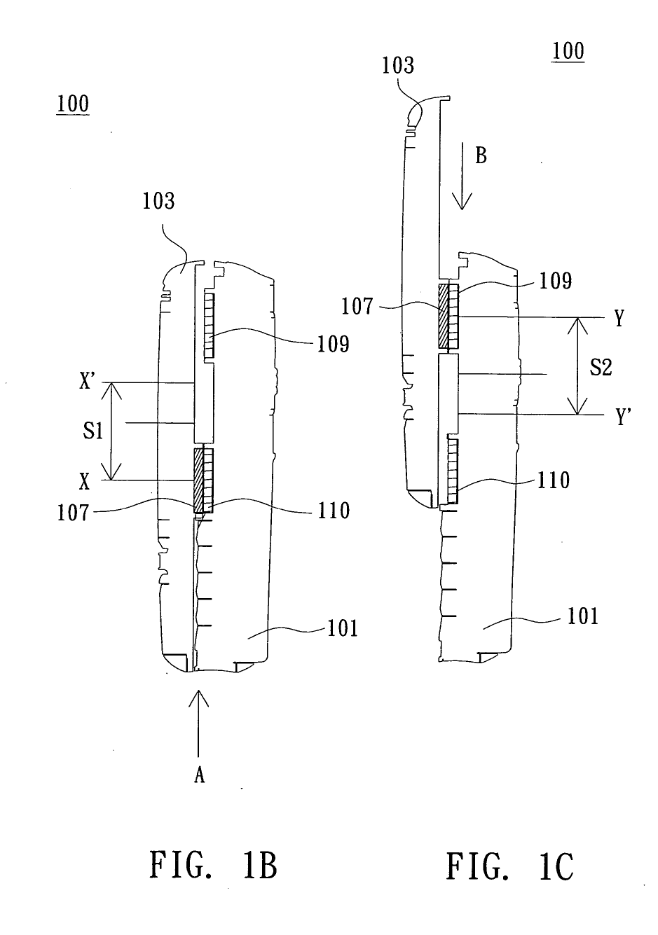

Referring to FIG. 1A, an explored diagram of a mobile phone according to a preferred embodiment of the invention is shown. The mobile phone 100 includes a main body 101, a slide cover 103, a first magnetic device 105, a second magnetic device 107 and a third magnetic device 109. The first magnetic device 105 is disposed at one end of the main body 101 and positioned in a first container 110. The second magnetic device 107 is disposed on the slide cover 103. The third magnetic device 109 is disposed at the other end of the main body 101 and positioned in a second container 112. The first magnetic device 105, the second magnetic device 107 and the third magnetic device 109 are magnets for instance. The first magnetic device 105 and the third magnetic device 109 have the same polarity while the second magnetic device 107 and the first magnetic device 109 are of different polarity. The main body 101 further includes a guide track 121, and the slide cover 103 can move along the guide track 121.

FIG. 1B is a lateral diagram of the mobile phone 100 with the slide cover located at the first positioning point. FIG. 1C is a lateral diagram of the mobile phone 100 with the slide cover located at the second positioning point. Due to the different polarity of the first magnetic device 105 and the second magnetic device 107, the second magnetic device 107 is attracted to the first magnetic device 105 whose position is the first positioning point of the second magnetic device 107 as the position X shown in FIG. 1B. Therefore, if the user would like to open the cover-slidable mobile phone 100, he/she has to move the second magnetic device 107 in the direction A by overcoming the magnetic force between the first magnetic device 105 and the second magnetic device 107. When the slide cover 103 is moved by the user to a position X′ along the direction A, that is, moved to a specific distance S1, the second magnetic device 107 will be attracted automatically by the third magnet device 109 to keep on moving to the second positioning point Y. At the time, the attracting force between the second magnetic device 107 and the third magnetic device 109 is larger than the friction force between the slide cover 103 and the main body 101. Therefore, at this stage, the slide cover 103 can automatically move to the position Y shown in FIG. 1C without annual movement.

According to the same reason, when the user needs to close the slide cover 103, he/she moves the slide cover 103 from the second positioning point Y along the direction B. When the slide cover 103 is moved to another specific distance S2, that is, to reach a position Y′, the first magnetic device 105 automatically attracts the second magnetic device 107 to move toward the first positioning point X until it returns to the initial state as shown in FIG. 1B. Of course, in the embodiment, the first magnetic device 105 and the third magnetic device 109 has substantially the same thickness such that the second magnetic device 107 can move smoothly between the first magnetic device 105 and the third magnetic device 109. Moreover, the first magnetic device 105 and the third magnetic device 109 can be both of N. or S. polarity as long as the second magnetic device 107 has different polarity from the first magnetic device 105 and the third magnetic device 109.

In the cover-slidable mobile phone disclosed by the above-mentioned embodiment of the invention, by using the feature that two magnetic devices of different polarity attract to each other, two magnetic devices of the same polarity are disposed on the main body while a magnetic device having different polarity from the two former ones is disposed on the slide cover. Therefore, the magnetic device of different polarity can move between the two magnetic devices of the same polarity. Or the second magnetic device can also be made of soft magnetic material which is easy for magnetization in order that it can be attracted by the first magnetic device and the third magnetic device. For the same reason, the first and the third magnetic devices can also be made of soft magnetic material. The user needs only to move the slide cover half the way and then the slide cover can be attracted by magnetic force to position automatically without extra specific mechanism. Therefore, the cost for designing the extra mechanism can be saved and the cost of the whole cover-slidable mobile phone can thus be reduced.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A mobile phone, comprising:
a main body;
a first magnetic device, disposed on the main body;
a slide cover, slidably connected to the main body, wherein the slide cover can slide relative to the main body; and
a second magnetic device, disposed on the slide cover, wherein when the slide cover moves to a distance relative to the main body, the first magnetic device attracts the second magnetic device so that the slide cover slides to a first positioning point.

2. The mobile phone according to claim 1, further comprising a third magnetic device disposed at the other end of the main body, wherein when the second magnetic device moves close to the third magnetic device, the third magnetic device attracts the second magnetic device so that the slide cover slides to a second positioning point.

3. The mobile phone according to claim 2, wherein the main body further comprises at least a first container and a second container for respectively containing the first magnetic device and the third magnetic device.

4. The mobile phone according to claim 2, wherein the first magnetic device and the second magnetic device have the same thickness.

5. The mobile phone according to claim 1, wherein the second magnetic device is made of soft magnetic material.

6. The mobile phone according to claim 1, wherein the first magnetic device has S. polarity and the second magnetic device has N. polarity.

7. The mobile phone according to claim 1, wherein the first magnetic device has N. polarity and the second magnetic device has S. polarity.

8. The mobile phone according to claim 1, wherein one of the first magnetic device and the second magnetic device is made of soft magnetic material.

9. The mobile phone according to claim 1, wherein the main body further comprises a guide track and the slide cover moves along the guide track.

10. A cover-slidable mobile phone, comprising:
a main body;
a slide cover, slidably connected to the main body;
a first magnetic device, disposed at one end of the main body;
a second magnetic device, disposed on the slide cover, wherein when the slide cover moves to a distance relative to the main body, the first magnetic device is attracted to the second magnetic device so that the slide cover slides to a first positioning point; and
a third magnetic device, disposed at the other end of the main body, wherein when the second magnetic device moves close to the third magnetic device, the third magnetic device attracts the second magnetic device so that the slide cover slides to a second positioning point.

11. The cover-slidable mobile phone according to claim 8, wherein the main body further comprises at least a first container and a second container for respectively containing the first magnetic device and the third magnetic device.

12. The cover-slidable mobile phone according to claim 8, wherein the first magnetic device and the second magnetic device have the same thickness and the second magnetic device can move smoothly between the first magnetic device and the third magnetic device.

13. The cover-slidable mobile phone according to claim 8, wherein the second magnetic device is made of soft magnetic material.

14. The cover-slidable mobile phone according to claim 8, wherein the first magnetic device has S. polarity and the second magnetic device has N. polarity.

15. The cover-slidable mobile phone according to claim 8, wherein the first magnetic device has N. polarity and the second magnetic device has S. polarity.

16. The cover-slidable mobile phone according to claim 8, wherein the first magnetic device and the third magnetic device are made of soft magnetic material.

17. The cover-slidable mobile phone according to claim 8, wherein the main body further comprises a guide track and the slide cover moves along the guide track.
